(19) United States
(12) Patent Application Publication
(10) Pub. No.: US 2008/0268380 A1
(43) Pub. Date: Oct. 30, 2008

(54) OPTICAL APPARATUS, MULTILAYER-FILM REFLECTIVE MIRROR, EXPOSURE APPARATUS, AND DEVICE

(76) Inventors: Katsuhiko Murakami, Sagamihara-shi (JP); Takaharu Komiya, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/098,238

(22) Filed: Apr. 4, 2008

Related U.S. Application Data
(60) Provisional application No. 60/907,957, filed on Apr. 24, 2007.

(51) Int. Cl. F21V 9/06; G03F 7/20

(52) U.S. Cl. 430/322; 359/359

(57) ABSTRACT

An optical apparatus comprises a plurality of multilayer-film reflective mirrors that are capable of reflecting an electromagnetic wave in an extreme ultraviolet region. The multilayer-film reflective mirrors are arranged along an optical axis of the electromagnetic wave, and at least two of the multilayer-film reflective mirrors have reflecting wavelength characteristics being different from each other, in a wavelength region other than the extreme ultraviolet region.

### CROSS-REFERENCE TO RELATED APPLICATION

This application is non-provisional application claiming benefit of provisional application No. 60/907,957, filed Apr. 24, 2007, the contents of which are incorporated herein by reference.

### BACKGROUND

1. Field of the Invention

The present invention relates to an optical apparatus that is provided with a multilayer-film reflective mirror, a multilayer-film reflective mirror, an exposure apparatus, and a device manufacturing method.

2. Description of Related Art

In an exposure apparatus for use in a photolithography process, there is proposed an EUV exposure apparatus as disclosed for example in U.S. Patent Application, Publication No. 2006/245058, in which Extreme Ultra-Violet (EUV) light is used as exposure light. In an optical system of an EUV exposure apparatus, a multilayer-film reflective mirror is used.

There is a possibility that light radiated from a light source of an EUV exposure apparatus includes not only light with a spectrum in the extreme ultraviolet region (soft X-ray region) but also light with spectra in the ultraviolet region, the visible region, and the infrared region. If light with a spectrum in a region other than the extreme ultraviolet region is irradiated onto a portion which is not expected to be irradiated with the light, that portion may experience increase in temperature by the light irradiation. In that case, there is a possibility that for example optical performance of the illumination optical system and the projection optical system deteriorates, leading to the deterioration in performance of the exposure apparatus. Furthermore, if light with a spectrum in a region other than the extreme ultraviolet region is irradiated onto the substrate, there is a possibility of the occurrence of defective exposure due to unnecessary exposure of the substrate or heating of the substrate.

In order to decrease undesirable light such as light with a spectrum in a region other than the extreme ultraviolet region, there can be conceived for example an addition of another film to the multilayer film. However, it may be difficult for a single multilayer-film reflective mirror to sufficiently reduce undesirable light in a wide wavelength range. Furthermore, depending on the configuration of the film, it may be difficult to sufficiently reduce undesirable light.

A purpose of some aspects in the present invention is to provide an optical apparatus that is capable of favorably reducing or eliminating undesirable light in a wide wavelength range, and of suppressing the deterioration in optical performance. Another purpose is to provide a multilayer-film reflective mirror that is capable of favorably reducing undesirable light. Still another purpose is to provide an exposure apparatus that is capable of suppressing the deterioration in performance and of favorably exposing a substrate, and to provide a device manufacturing method using the exposure apparatus.

### SUMMARY

According to a first aspect exemplifying the present invention, there is provided an optical apparatus, comprising a plurality of multilayer-film reflective mirrors that are capable of reflecting an electromagnetic wave in an extreme ultraviolet region, in which the multilayer-film reflective mirrors are arranged along an optical axis of the electromagnetic wave, and at least two of the multilayer-film reflective mirrors have reflecting wavelength characteristics being different from each other, in a wavelength region other than the extreme ultraviolet region.

According to the first aspect exemplifying the present invention, undesirable light can be favorably decreased or removed in a wide wavelength region, and the deterioration in optical performance can be suppressed.

According to a second aspect exemplifying the present invention, there is provided a multilayer-film reflective mirror, comprising: a base; a multilayer film that comprises a first layer and a second layer alternately laminated on the base, and is capable of reflecting an electromagnetic wave in an extreme ultraviolet region; and an absorption layer that is formed so as to be in contact with a surface of the multilayer film and that absorbs an electromagnetic wave in at least a part of a wavelength region other than the extreme ultraviolet region, in which the absorption layer comprises: a first absorption layer, made of a first substance, that is formed so as to be in contact with the surface of the multilayer film; and a second absorption layer, made of a second substance, that is formed so as to be in contact with a surface of the first absorption layer.

According to the second aspect exemplifying the present invention, undesirable light can be favorably decreased or eliminated in a wide wavelength region, and the deterioration in optical performance can be suppressed.

According to a third aspect exemplifying the present invention, there is provided an exposure apparatus that exposes a substrate with exposure light, comprising the optical apparatus of one of the above-described aspects.

According to the third aspect exemplifying the present invention, a substrate can be favorably exposed because the optical apparatus in which the deterioration in optical performance is suppressed is provided.

According to a fourth aspect exemplifying the present invention, there is provided a device manufacturing method, comprising: exposing a substrate by use of the exposure apparatus of one of the above-mentioned aspects; and developing the exposed substrate.

According to the fourth aspect exemplifying the present invention, devices can be manufactured by use of the exposure apparatus that can favorably expose a substrate.

According to the some aspects in the present invention, undesirable light can be favorably decreased or eliminated, and the deterioration in optical performance can be suppressed. Therefore, a substrate can be favorably exposed, and devices with desired performance can be manufactured.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is a schematic diagram showing one example of an exposure apparatus according to a first embodiment.

FIG. 2 is a diagram for explaining an optical characteristic of an optical apparatus according to the first embodiment.

FIG. 3 is a schematic diagram showing one example of a multilayer-film reflective mirror according to the first embodiment.

FIG. 4 is a schematic diagram showing one example of a multilayer-film reflective mirror according to the first embodiment.

FIG. 5 is a diagram for explaining an optical characteristic of a multilayer-film reflective mirror according to the first embodiment.

FIG. 6 is a diagram for explaining an optical characteristic of a multilayer-film reflective mirror according to the first embodiment.

FIG. 7 is a diagram for explaining an optical characteristic of an optical apparatus according to the first embodiment.

FIG. 8 is a schematic diagram showing one example of a multilayer-film reflective mirror according to a second embodiment.

FIG. 9 is a schematic diagram showing one example of a multilayer-film reflective mirror according to the second embodiment.

FIG. 10 is a diagram for explaining an optical characteristic of a multilayer-film reflective mirror according to the second embodiment.

FIG. 11 is a diagram for explaining an optical characteristic of a multilayer-film reflective mirror according to the second embodiment.

FIG. 12 is a diagram for explaining an optical characteristic of an optical apparatus according to the second embodiment.

FIG. 13 is a schematic diagram showing one example of a multilayer-film reflective mirror according to a third embodiment.

FIG. 14 is a diagram for explaining an optical characteristic of a multilayer-film reflective mirror according to the third embodiment.

FIG. 15 is a diagram for explaining an optical characteristic of an optical apparatus according to the third embodiment.

FIG. 16 is a schematic diagram showing one example of a multilayer-film reflective mirror according to a fourth embodiment.

FIG. 17 is a diagram for explaining an optical characteristic of a multilayer-film reflective mirror according to the fourth embodiment.

FIG. 18 is a diagram for explaining an optical characteristic of an optical apparatus according to the fourth embodiment.

FIG. 19 is a schematic diagram showing one example of a multilayer-film reflective mirror in a fifth embodiment.

FIG. 20 is a schematic diagram showing one example of a multilayer-film reflective mirror in the fifth embodiment.

FIG. 21 shows a reflecting wavelength characteristic of the multilayer-film reflective mirror shown in FIG. 19.

FIG. 22 shows a reflecting wavelength characteristic of the multilayer-film reflective mirror shown in FIG. 20.

FIG. 23 is a schematic diagram showing another example of a multilayer-film reflective mirror in the fifth embodiment.

FIG. 24 shows a reflecting wavelength characteristic of the multilayer-film reflective mirror shown in FIG. 23.

FIG. 25 is a flow chart for explaining one example of manufacturing steps for a micro device.

### DESCRIPTION OF EMBODIMENTS

Hereunder is a description of embodiments of the present invention with reference to the drawings. However, the present invention is not limited to this description. In the following description, an XYZ rectangular co-ordinate system is established, and the positional relationship of respective members is described with reference to this XYZ rectangular co-ordinate system. A predetermined direction within a horizontal plane is made the X axis direction, a direction orthogonal to the X axis direction within the horizontal plane is made the Y axis direction, and a direction orthogonal to both the X axis direction and the Y axis direction (that is, a perpendicular direction) is made the Z axis direction. Furthermore, rotation (tilt) directions about the X axis, the Y axis and the Z axis, are made the θX, the θY, and the θZ directions respectively.

### First Embodiment

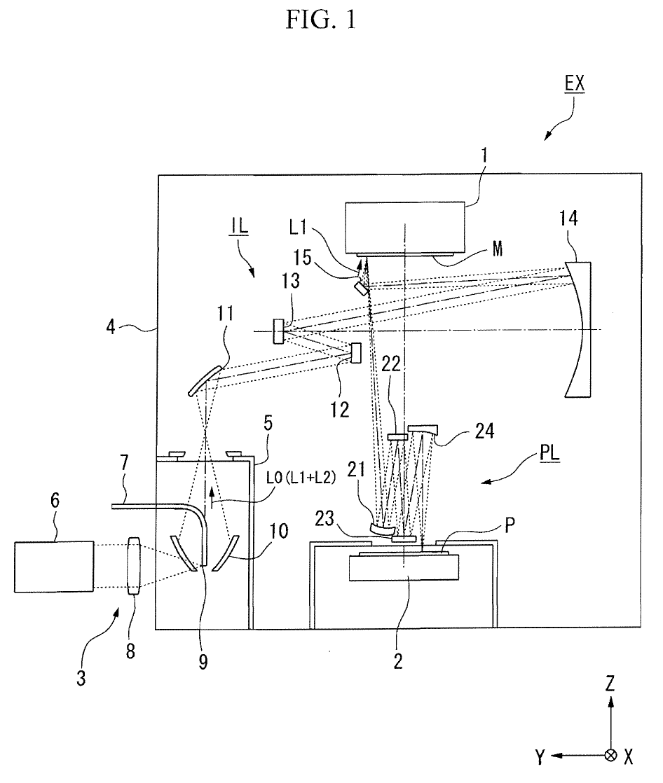

A first embodiment will be described. FIG. 1 is a schematic block diagram showing one example of an exposure apparatus EX according to a first embodiment. In FIG. 1, the exposure apparatus EX includes: a mask stage 1 capable of moving while holding a mask M on which a pattern is formed; a substrate stage 2 capable of moving while holding a substrate P for forming devices; a light source apparatus 3 for generating exposure light; an illumination optical system IL for illuminating a mask M held on the mask stage 1 with exposure light EL emitted from the light source apparatus 3; a projection optical system PL for projecting an image of a pattern on the mask M illuminated by the exposure light onto the substrate P.

The exposure apparatus EX in the present embodiment is an EUV exposure apparatus that exposes the substrate P with extreme ultraviolet light. Extreme ultraviolet light is an electromagnetic wave in an extreme ultraviolet region (soft X-ray region) at a wavelength of for example approximately 5 to 50 nm. In the following description, extreme ultraviolet light is appropriately referred to as EUW light.

The substrate P includes one a film (photosensitive film) of a photosensitive material (photoresist) or the like is formed on a base material such as a semiconductor wafer or the like. The mask M includes a reticle formed with a device pattern which is projected onto the substrate P. In the present embodiment, EUV light is used as exposure light, and the mask M is a reflecting mask with a multilayer film capable of reflecting the EUV light. The multilayer film of the reflecting mask includes, for example, a Mo/Si multilayer film or a Mo/Be multilayer film. The exposure apparatus EX illuminates a reflection surface (pattern formation surface) of a mask M on which is formed a multilayer film, with the exposure light (EUV light), and exposes the substrate P with the exposure light reflected by the mask M. As one example, in the present embodiment, EUV light at a wavelength of 13.5 nm is used as the exposure light.

Moreover, the exposure apparatus EX includes a chamber apparatus 4 that forms a predetermined space through which at least the exposure light passes and that has a vacuum system for rendering the predetermined space to a vacuum state (for example, 1.3×10⁻³ Pa or below).

The light source apparatus 3 in this embodiment is a laser-excited plasma light source. It includes: a housing 5; a laser apparatus 6 for emitting laser light; and a supply member 7 for supplying a target material such as a xenon gas into the housing 5. The laser apparatus 6 generates laser light at a wavelength in the infrared region and the visible region. The laser apparatus 6 includes for example the YAG laser by semiconductor laser production, the excimer laser, or the like.

Furthermore, the light source apparatus 3 includes a collective optical system 8 for condensing laser light emitted from the laser apparatus 6. The collective optical system 8 condenses the laser light emitted from the laser apparatus 6 at a position 9 inside the housing 5. The supply member 7 has a supply port for supplying a target material to the position 9. The laser light condensed by the collective optical system 8 is irradiated onto the target material supplied by the supply member 7. The target material irradiated with the laser light is heated by the energy of the laser light to a high temperature, is excited to a plasma state, and generates light including EUV light when making a transition to a low potential state. The light generated at a front end of the supply member 7 is reflected by a condensing mirror (condenser) 10 to be condensed. The condensing mirror 10 includes a multilayer-film reflective mirror that is provided with a multilayer film capable of reflecting EUV light. The light via the condensing mirror 10 is incident on an optical element 11 of the illumination optical system IL which is arranged outside the housing 5. The optical element 11 includes a collimator mirror. Note that the light source apparatus 3 may be a plasma discharge apparatus.

There is a possibility that the light source apparatus 3 generates not only light with a spectrum in the extreme ultraviolet region (EUV light) but also light with spectra in the ultraviolet region, the visible region, and the infrared region. That is, there is a possibility that the light emitted from the light source apparatus 3 includes: light (electromagnetic wave) in the extreme ultraviolet region; and light (electromagnetic wave) in a wavelength region other than the extreme ultraviolet region. In the following description, light emitted from the light source apparatus 3 which is in a wavelength region other than the extreme ultraviolet region such as the ultraviolet region, the visible region, and the infrared region is appropriately referred to as OoB (Out of Band) light.

That is, in the present embodiment, light LO emitted from the light source apparatus 3 includes: EUV light (exposure light) L1 in the extreme ultraviolet region; and OoB light L2 in a wavelength region other than the extreme ultraviolet region In the present embodiment, the OoB light L2 has a wavelength longer than that of the EUV light L1.

The illumination optical system IL illuminates the mask M with the exposure light L1 from the light source apparatus 3. The illumination optical system IL includes a plurality of optical elements 11, 12, 13, 14, and 15. It illuminates a predetermined illumination region on the mask M with the exposure light L1 of a uniform luminance distribution. Each of the optical elements 11 to 15 includes a multilayer-film reflective mirror provided with a multilayer film capable of reflecting the EUV light L1. The exposure light L1 that has been illuminated by the illumination optical system IL and reflected by the reflection surface of the mask M is incident in the projection optical system PL from the object plane side of the projection optical system PL.

The mask stage 1 is a stage with six degrees of freedom that is capable of moving in the six directions of: the X axis, the Y axis, the Z axis, the θX, the θY and the θZ directions while holding the mask M. In the present embodiment, the mask stage 1 holds the mask M so that the reflection surface of the mask M is substantially parallel to the XY plane. Position information (position information related to the X axis, the Y axis, and the θZ directions) of the mask stage 1 (the mask M) is measured by an interference system including a laser interferometer (not shown in the figure). Furthermore, surface position information of the surface of the mask M held on the mask stage 1 (position information related to the Z axis, the θX, and the θY directions) is detected by a focus leveling detection system (not shown in the figure). The position of the mask M held on the mask stage 1 is controlled based on the detection results of the interference system and the detection results of the focus leveling detection system.

The projection optical system PL includes a plurality of optical elements 21, 22, 23, and 24. It projects an image of the pattern on the mask M onto the substrate P at a predetermined projection magnification. Each of the optical elements 21 to 24 includes a multilayer-film reflective mirror provided with a multilayer film capable of reflecting the EUV light L1. The exposure light L1 that has been incident in the projection optical system PL from the object plane side of the projection optical system PL is emitted to the image plane side of the projection optical system PL to be incident on the substrate P. The image of the pattern on the mask M which is illuminated with the exposure light L1 is projected via the projection optical system PL onto the substrate P on which is formed a photosensitive film.

The substrate stage 2 is a stage with six degrees of freedom that is capable of moving in the six directions of: the X axis, the Y axis, the Z axis, the θX, the θY and the θZ directions while holding the substrate P. In the present embodiment, the substrate stage 2 holds the substrate P so that the surface of the substrate P is substantially parallel to the XY plane. Position information (position information related to the X axis, the Y axis, and the θZ directions) of the substrate stage 2 (the substrate P) is measured by an interference system including a laser interferometer (not shown in the figure). Furthermore, surface position information of the surface of the substrate P held on the substrate stage 2 (position information related to the Z axis, the θX, and the θY directions) is detected by a focus leveling detection system (not shown in the figure). The position of the substrate P held on the substrate stage 2 is controlled based on the detection results of the interference system and the detection results of the focus leveling detection system.

In order to project the image of the pattern on the mask M to the substrate P by use of the exposure light L1, the mask M is held on the mask stage 1, and the substrate P is held on the substrate stage 2, as shown in FIG. 1. When the exposure light (EUV light) L1 is emitted from the light source apparatus 3, the illumination optical system IL uses each of the plurality of optical elements 11 to 15 made of a multilayer-film reflective mirror to reflect the exposure light L1 from the light source apparatus 3, to thereby guide the exposure light L1 to the mask M. The mask M is illuminated with the exposure light L1 from the illumination optical system IL. The exposure light L1 that has been irradiated onto the reflection surface of the mask M and reflected by the reflection surface thereof is incident in the projection optical system PL. The projection optical system PL uses each of the plurality of optical elements 21 to 24 made of a multilayer-film reflective mirror to reflect the exposure light L1 from the mask M, to thereby guide the exposure light L1 to the substrate P. The photosensitive substrate P is exposed to the exposure light L1 from the projection optical system PL. As a result, the image of the pattern on the mask M is projected onto the substrate P via the projection optical system PL.

In the present embodiment, the illumination optical system IL includes at least two multilayer-film reflective mirrors that suppress (or reduce) a reflection of light (electromagnetic wave) in at least a part of a wavelength region other than the extreme ultraviolet region, that is, the OoB light L2. In the present embodiment, the wavelength regions in which the reflections are suppressed by the at least two multilayer-film reflective mirrors are different from each other. That is, of the plurality of multilayer-film reflective mirrors of the illumination optical system IL, a first multilayer-film reflective mirror mainly suppresses OoB light in a first wavelength region, and a second multilayer-film reflective mirror mainly suppresses OoB light in a second wavelength region different from the first wavelength region.

As described above, in the present embodiment, the wavelength of the OoB light L2 is longer than that of the EUV light L1. That is, in the present embodiment, the wavelength region in which the reflection is suppressed by the multilayer-film reflective mirror includes a wavelength region which is longer than the extreme ultraviolet region. The wavelength region which is longer than the extreme ultraviolet region includes at least one of the ultraviolet region, the visible region, and the infrared region.

In the present embodiment, a case will be described by way of example where a multilayer-film reflective mirror that suppresses the reflection of the OoB light L2 suppresses the reflection of the OoB light L2 in an ultraviolet region which is longer than the extreme ultraviolet region.

As will be described later, in the present embodiment, a multilayer-film reflective mirror that suppresses the reflection of the OoB light L2 includes an absorption layer that absorbs light (electromagnetic wave) in at least a part of a wavelength region other than the extreme ultraviolet region. The multilayer-film reflective mirror provided with the absorption layer absorbs the OoB light L2 to thereby suppress the reflection of the OoB light L2.

In the present embodiment, an absorption layer provided on the first multilayer-film reflective mirror, of the plurality of multilayer-film reflective mirrors of the illumination optical system IL, is adjusted according to the first wavelength region so that the first multilayer-film reflective mirror can favorably suppress the reflection of OoB light L2 in the first wavelength region, and an absorption layer provided on the second multilayer-film reflective mirror thereof is adjusted according to the second wavelength region so that the second multilayer-film reflective mirror can favorably suppress the reflection of OoB light L2 in the second wavelength region. The absorption layer of the first multilayer-film reflective mirror is different in configuration from the absorption layer of the second multilayer-film reflective mirror. The configuration of the absorption layer includes at least one of the type (materiality) of the substance which forms the absorption layer and the thickness of the absorption layer.

That is, it is adjusted such that the absorption layer of the first multilayer-film reflective mirror mainly absorbs the OoB light L2 in the first wavelength region, and that the absorption layer of the second multilayer-film reflective mirror mainly absorbs the OoB light L2 in the second wavelength region different from the first absorption region. In other words, in the present embodiment, the wavelength with high absorption efficiency for the absorption layer of the first multilayer-film reflective mirror is different from that with high absorption efficiency for the absorption layer of the second multilayer-film reflective mirror.

The illumination optical system IL in the present embodiment includes: the first multilayer-film reflective mirror capable of mainly suppressing the reflection of the OoB light L2 in the first wavelength region; and the second multilayer-film reflective mirror capable of mainly suppressing the reflection of the OoB light L2 in the second wavelength region. Therefore, with those first multilayer-film reflective mirror and second multilayer-film reflective mirror combined, the OoB light L2 can be sufficiently reduced or eliminated in a wide wavelength region.

For example, by adjusting the configuration of the first multilayer-film reflective mirror so that the reflection of the OoB light L2 with a short wavelength can be sufficiently suppressed by the first multilayer-film reflective mirror, and adjusting the configuration of the second multilayer-film reflective mirror so that the reflection of the OoB light L2 with a long wavelength can be sufficiently suppressed by the second multilayer-film reflective mirror, the OoB light L2 in a wide wavelength region can be absorbed by both of the first multilayer-film reflective mirror and the second multilayer-film reflective mirror, causing the reflection thereof to be suppressed. Therefore, the incidence of the OoB light L2 to objects on the downstream side of the optical path of the illumination optical system IL such as the mask M, the projection optical system PL, and the substrate P can be favorably suppressed.

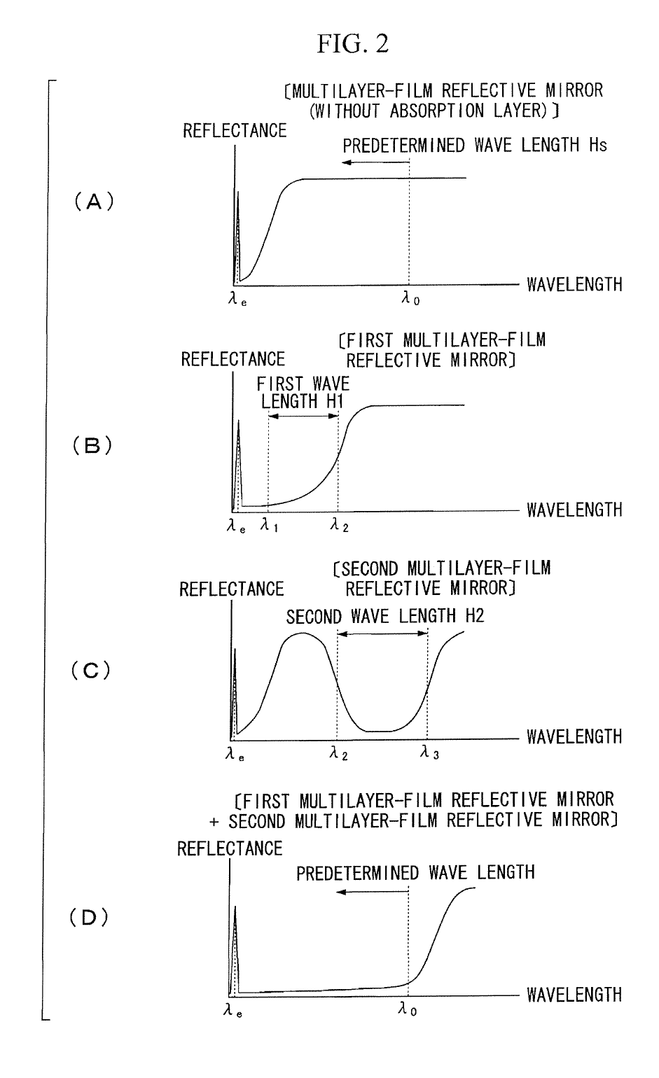

Part (A) of FIG. 2 schematically shows one example of a reflecting wavelength characteristic of a multilayer-film reflective mirror without an absorption layer, with respect to OoB light L2. The horizontal axis represents the wavelength of light (electromagnetic wave) incident on the multilayer-film reflective mirror. The vertical axis represents the reflectance of the multilayer-film reflective mirror for the incident light. In part (A) of FIG. 2, a wavelength λ₀ is a maximum value of the wavelengths, in the ultraviolet region, at which the photosensitive film on the substrate P is exposed (the photosensitive film has a sensitivity). That is, the photosensitive film on the substrate P is exposed not only by the EUV light L1 at a wavelength of λₑ in the extreme ultraviolet region, but also by the OoB light L2 in a wavelength region shorter than the wavelength λ₀ in the ultraviolet region.

In the following description, the wavelength region, other than the extreme ultraviolet region, in which the photosensitive film on the substrate P is exposed (the photosensitive film has a sensitivity) is appropriately referred to as predetermined wavelength region Hs. In the present embodiment, the predetermined wavelength region Hs includes an ultraviolet region that is longer than a wavelength λ_{c} in the extreme ultraviolet region and shorter than the wavelength λ₀, in other words, a wavelength region from a wavelength with a minimum value to the wavelength λ₀ in the ultraviolet region.

A multilayer-film reflective mirror with the reflecting wavelength characteristic as shown in part (A) of FIG. 2 has a high reflectance not only for the EUV light L1, but also for the OoB light L2 in the predetermined wavelength region Hs. Therefore, in the case where multilayer-film reflective mirrors with the reflecting wavelength characteristic as shown in part (A) of FIG. 2 are used as optical elements of the illumination optical system IL, the multilayer-film reflective mirrors reflect, of the light LO emitted from the light source apparatus 3, not only the EUV light L1 but also the OoB light L2, which exposes the photosensitive film on the substrate P. In this case, the OoB light L2 reaches the mask M, and then reaches the substrate P via the mask M and the projection optical system PL. If the OoB light L2 is irradiated onto the substrate P, there is a possibility of the occurrence of defective exposure due to unnecessarily exposure of the substrate P or heating of the substrate P.

Part (B) of FIG. 2 schematically shows one example of a reflecting wavelength characteristic of a first multilayer-film reflective mirror which mainly suppresses OoB light L2 in a first wavelength region HI, with respect to the OoB light L2. The horizontal axis represents the wavelength of light (electromagnetic wave) incident on the multilayer-film reflective mirror. The vertical axis represents the reflectance of the multilayer-film reflective mirror for the incident light. As shown in part (B) of FIG. 2, the reflectance of the first multilayer-film reflective mirror for the OoB light L2 in the first wavelength region H1 from the wavelength λ₁ to the wavelength λ₂ is suppressed. The wavelengths λ₁ and λ₂ are in the ultraviolet region. They are shorter than the wavelength λ₀ and longer than the wavelength in the extreme ultraviolet region (the wavelength of the EUV light L1). That is, the first wavelength region H1 is a part of the predetermined wavelength region Hs. Note that the wavelength λ₂ is longer than the wavelength λ₁.

In the present embodiment, the configuration of the absorption layer of the first multilayer-film reflective mirror is adjusted so as to suppress the reflection of the wavelength in the first wavelength region H1. As described above, the first wavelength region H1 is a part of the predetermined wavelength region Hs, and the first multilayer-film reflective mirror suppresses the reflection of a wavelength in a wavelength region that is longer than the extreme ultraviolet region and is at least a part of the predetermined wavelength region Hs.

However, the first multilayer-film reflective mirror cannot sufficiently suppress the reflection of the light in the wavelength region, of the predetermined wavelength region Hs, from the wavelength λ₂ to the wavelength λ₀. Therefore, in the case where of the plurality of multilayer-film reflective mirrors of the illumination optical system IL, only the first multilayer-film reflective mirror is provided with an absorption layer and the other multilayer-film reflective mirrors are not provided with an absorption layer, the light in the wavelength region, of the OoB light L2 emitted from the light source apparatus 3, from the wavelength λ₂ to the wavelength λ₀ reaches the mask M, and then reaches the substrate P via the mask M and the projection optical system PL. Even in this case, there is a possibility of the occurrence of defective exposure.

Part (C) of FIG. 2 schematically shows one example of a reflecting wavelength characteristic of a second multilayer-film reflective mirror which mainly suppresses OoB light L2 in a second wavelength region H2, with respect to the OoB light L2. The horizontal axis represents the wavelength of light (electromagnetic wave) incident on the multilayer-film reflective mirror. The vertical axis represents the reflectance of the multilayer-film reflective mirror for the incident light. As shown in part (C) of FIG. 2, the reflectance of the second multilayer-film reflective mirror for the OoB light L2 in the second wavelength region H2 from the wavelength λ₂ to the wavelength λ₃ is suppressed. The wavelengths λ₂ and λ₃ are in the ultraviolet region, and hence are longer than the wavelength in the extreme ultraviolet region (the wavelength of the EUV light L1). In the present embodiment, the wavelength λ₂ is shorter than the wavelength λ₀, and the wavelength λ₃ is longer than the wavelength λ₀. That is, the second wavelength region H2 includes at least a part of the predetermined wavelength region Hs.

In the embodiment, the configuration of the absorption layer of the second multilayer-film reflective mirror is adjusted so as to suppress the reflection of the wavelength in the second wavelength region H2. As described above, the second wavelength region H2 includes a part of the predetermined wavelength region Hs, and the second multilayer-film reflective mirror suppresses the reflection of a wavelength in a wavelength region that is longer than the extreme ultraviolet region and is at least a part of the predetermined wavelength region Hs.

However, the second multilayer-film reflective mirror cannot sufficiently suppress the reflection of the light in the wavelength region, of the predetermined wavelength region Hs, from the wavelength with the minimum value to the wavelength λ₂. Therefore, in the case where of the plurality of multilayer-film reflective mirrors of the illumination optical system IL, only the second multilayer-film reflective mirror is provided with an absorption layer and the other multilayer-film reflective mirrors are not provided with an absorption layer, the light in the wavelength region, of the OoB light L2 emitted from the light source apparatus 3, from the wavelength with the minimum value in the predetermined wavelength region Hs to the wavelength λ₂ wavelength reaches the mask M, and then reaches the substrate P via the mask M and the projection optical system PL. Even in this case, there is a possibility of the occurrence of defective exposure.

Part (D) of FIG. 2 schematically shows one example of a total reflecting wavelength characteristic of a combination of a first multilayer-film reflective mirror which mainly suppresses OoB light L2 in a first wavelength region Hi and a second multilayer-film reflective mirror which mainly suppresses OoB light L2 in a second wavelength region H2, with respect to the OoB light L2. The horizontal axis represents the wavelength of light (electromagnetic wave) incident on the multilayer-film reflective mirror. The vertical axis represents the reflectance of the multilayer-film reflective mirror for the incident light. With the combination of the first multilayer-film reflective mirror and the second multilayer-film reflective mirror, the reflection of the OoB light L2 can be suppressed in a wide wavelength region from the wavelength λ₁ to the wavelength λ₃, as shown in part (D) of FIG. 2. Therefore, the incidence of the OoB light L2 to objects on the downstream side of the optical path of the illumination optical system IL such as the mask M, the projection optical system PL, and the substrate P can be favorably suppressed. With the combination of the first multilayer-film reflective mirror and the second multilayer-film reflective mirror, the wavelength region in which the reflection is suppressed is longer than the extreme ultraviolet region and includes at least a part of a wavelength region which is the predetermined wavelength region Hs. Therefore, unnecessary exposure of the substrate P can be suppressed. In the example shown in part (D) of FIG. 2, by the first multilayer-film reflective mirror and the second multilayer-film reflective mirror, the reflection of substantially all the wavelengths in the predetermined wavelength region Hs which expose the photosensitive film on the substrate P can be suppressed.

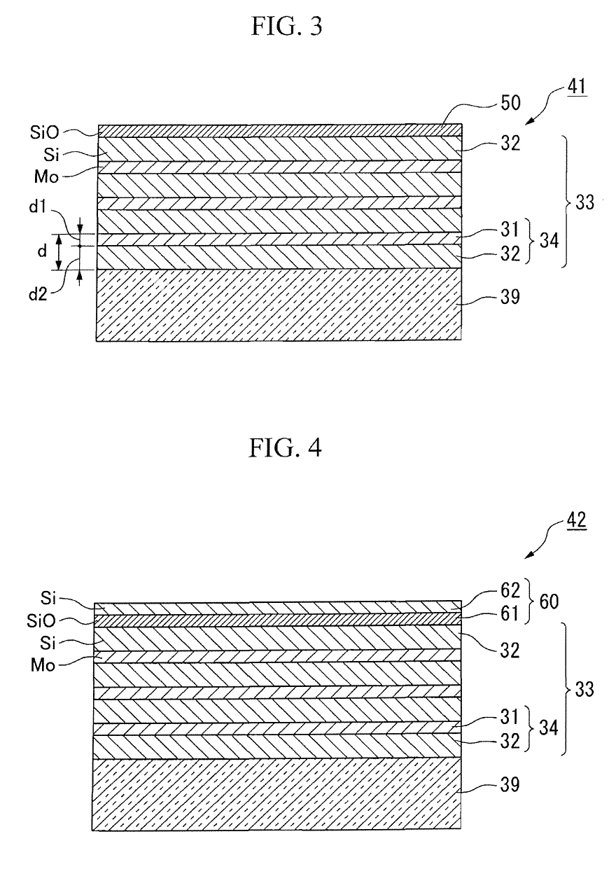

Next is a description of a multilayer-film reflective mirror provided with an absorption layer. FIG. 3 is a schematic diagram showing a first multilayer-film reflective mirror 41 according to the present embodiment. FIG. 4 is a schematic diagram showing a second multilayer-film reflective mirror 42 according to the present embodiment. In the present embodiment, of the condensing mirror 10 and the plurality of multilayer-film reflective mirrors 11 to 15 of the illumination optical system IL, at least one multilayer-film reflective mirror is the first multilayer-film reflective mirror 41 shown in FIG. 3, and at least one multilayer-film reflective mirror is the second multilayer-film reflective mirror 42 shown in FIG. 4.

First, the first multilayer-film reflective mirror 41 will be described. In FIG. 3, the first multilayer-film reflective mirror 41 includes: a base 39; a multilayer film 33 that includes first layers 31 and second layers 32 alternately laminated on the base 39 at a predetermined periodic length and is capable of reflecting the EUV light L1; and an absorption layer 50 that is formed so as to be in contact with a surface of the multilayer film 33 for absorbing the OoB light L2 in at least a part of a wavelength region (ultraviolet region) other than the extreme ultraviolet region.

The base 39 is formed of for example an ultra low-expansion glass. As the base 39, for example ULE manufactured by Coming Incorporated, Zerodur (registered trademark) manufactured by SCHOTT AG, or the like may be used.

The multilayer film 33 includes first layers 31 and second layers 32 alternately laminated at a predetermined periodic length “d”. The periodic length “d” is a sum (d₁+d₂) of a thickness “d₁” of the first layer 31 and a thickness “d₂” of the second layer 32. Based on the theory of optical interference, the thickness “d₁” of the first layer 31 and the thickness “d₂” of the second layer 32 are respectively specified so that the phases of the reflecting waves reflected respectively from the interfaces of first layer 31 and the second layer 32 coincide with each other. For example, the multilayer film 33 is capable of reflecting the EUV light with a high reflectance of for example 60% or greater.

As one example, the periodic length “d” in the present embodiment is 7 nm. In the following description, a pair of the first layer 31 and the second layer 32 is appropriately referred to as layer pair 34.

Note that the periodic length “d” (the thickness of the layer pair 34) is adjusted according to the incident angle of the EUV light L1 with respect to the surface of the multilayer film 33. In the present embodiment, the periodic length “d” (the thickness of the layer pair 34) is adjusted so that the EUV light L1 can be favorably reflected in the case where the incident angle of the EUV light L1 with respect to the surface of the multilayer film 33 is approximately 90 degrees.

On the base 39, there are laminated for example tens to hundreds of layer pairs 34. As one example, in the present embodiment, fifty layer pairs 34 are laminated on the base 39. Note that in the figure, some of the layer pairs 34 are omitted.

The first layer 31 is formed of a substance having a refractive index, to the EUV light L1, of which a difference between the refractive index and the refractive index of a vacuum is relatively large. The second layer 32 is formed of a substance having a refractive index, to the EUV light L2, of which a difference between the refractive index and the refractive index of a vacuum is relatively small. That is, the difference between the refractive index of the first layer 31 for the EUW light and the refractive index of a vacuum is larger than that of the second layer 32. In the present embodiment, the first layer (heavy-atom layer) 31 is formed of molybdenum (Mo), and the second layer (light-atom layer) 32 is formed of silicon (Si). That is, the multilayer film 33 in the present embodiment is a Mo/Si multilayer film in which molybdenum layers (Mo layers) and silicon layers (Si layers) are alternately laminated.

The refractive index of a vacuum n=1. Furthermore, with respect to the EUV light having a wavelength of for example 13.5 nm, the refractive index of molybdenum n_{M0}=0.92, and the refractive index of silicon n_{Si}=0.998. Thus, the second layer 32 is formed of a substance whose refractive index with respect to the EUV light L1 is substantially equal to that of a vacuum.

Furthermore, in the present embodiment, the surface of the multilayer film 33 is formed of a second layer (Si layer) 32. As a result, oxidization of the surface of the multilayer film 33 can be suppressed.

In FIG. 3, the absorption layer 50 of the first multilayer-film reflective mirror 41 is formed of silicon monoxide (SiO). As one example, in the present embodiment, the absorption layer 50 has a thickness of 29 nm.

Next, the second multilayer-film reflective mirror 42 will be described. In FIG. 4, the second multilayer-film reflective mirror 42 includes: a base 39; a multilayer film 33 that includes first layers 31 and second layers 32 alternately laminated on the base 39 at a predetermined periodic length “d” and is capable of reflecting the EUV light L1; and an absorption layer 60 that is formed so as to be in contact with a surface of the multilayer film 33 for absorbing the OoB light L2 in at least a part of a wavelength region (ultraviolet region) other than the extreme ultraviolet region.

In the present embodiment, the base 39, the first layers 31, and the second layers 32 of the second multilayer-film reflective mirror 42 are equivalent to the base 39, the first layers 31, and the second layers 32 of the first multilayer-film reflective mirror 41. A description of the base 39, the first layers 31, and the second layers 32 of the second multilayer-film reflective mirror 42 is omitted.

In FIG. 4, the absorption layer 60 of the second multilayer-film reflective mirror 42 is formed of two absorption layers. The absorption layer 60 includes: a first absorption layer 61 made of a first substance and formed so as to be in contact with a surface of the multilayer film 33; and a second absorption layer 62 made of a second substance and formed so as to be in contact with a surface of the first absorption layer 61. In the present embodiment, the first absorption layer 61 is formed of silicon monoxide (SiO), and the second absorption layer 62 is formed of silicon (Si). As one example, in the present embodiment, the first absorption layer 61 has a thickness of 16 nm, and the second absorption layer 62 has a thickness of 9 nm.

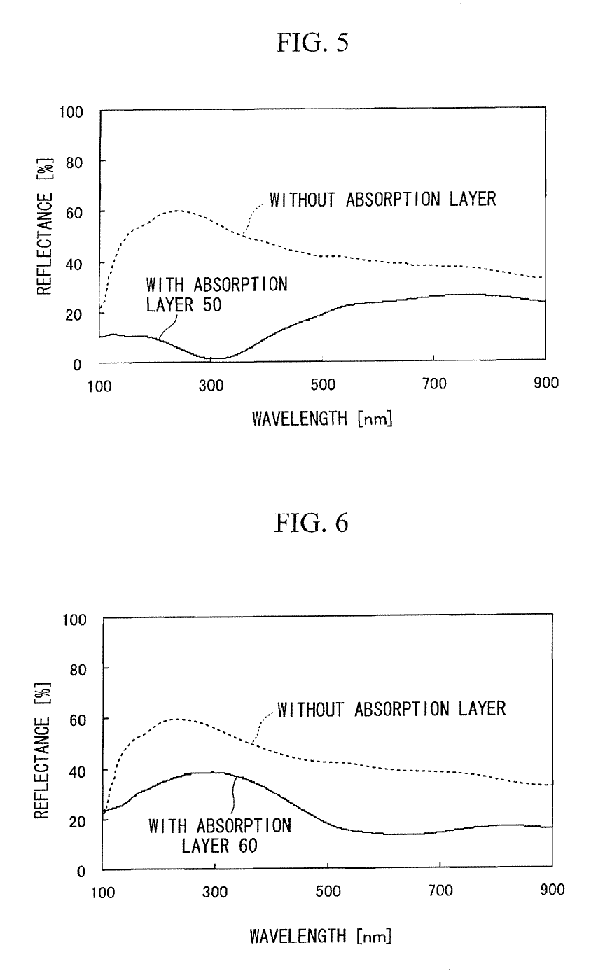

FIG. 5 shows a reflecting wavelength characteristic of the first multilayer-film reflective mirror 41 shown in FIG. 3. The horizontal axis represents the wavelength of the OoB light L2 incident on the multilayer-film reflective mirror. The vertical axis represents the reflectance of the multilayer-film reflective mirror for the incident OoB light L2. In FIG. 5, the solid line represents a reflectance of the first multilayer-film reflective mirror 41 for the OoB light L2 in a wavelength region from a wavelength of 100 nm to a wavelength of 900 nm. FIG. 5 shows the case the incident angle of light with respect to the surface of the multilayer film 33 (the surface of the absorption layer 50) is approximately 90 degrees. Note that as a comparative example, the dashed line represents a reflectance of a multilayer-film reflective mirror without an absorption layer for the OoB light L2.

As shown in FIG. 5, the first multilayer-film reflective mirror 41 in the present embodiment can favorably suppress the reflection of the OoB light L2 in a wavelength region near a wavelength of 300 nm.

FIG. 6 shows a reflecting wavelength characteristic of the second multilayer-film reflective mirror 42 shown in FIG. 4. The horizontal axis represents the wavelength of the OoB light L2 incident on the multilayer-film reflective mirror. The vertical axis represents the reflectance of the multilayer-film reflective mirror with respect to the incident OoB light L2. In FIG. 6, the solid line represents a reflectance of the second multilayer-film reflective mirror 42 for the OoB light L2 in a wavelength region from a wavelength of 100 nm to a wavelength of 900 nm. FIG. 6 shows the case where the incident angle of light with respect to the surface of the multilayer film 33 (the surface of the absorption layer 60) is approximately 90 degrees. Note that as a comparative example, the dashed line represents a reflectance of a multilayer-film reflective mirror without an absorption layer for the OoB light L2.

As shown in FIG. 6, the second multilayer-film reflective mirror 42 in the present embodiment can favorably suppress the reflection of the OoB light L2 in a wavelength region near a wavelength of 600 nm.

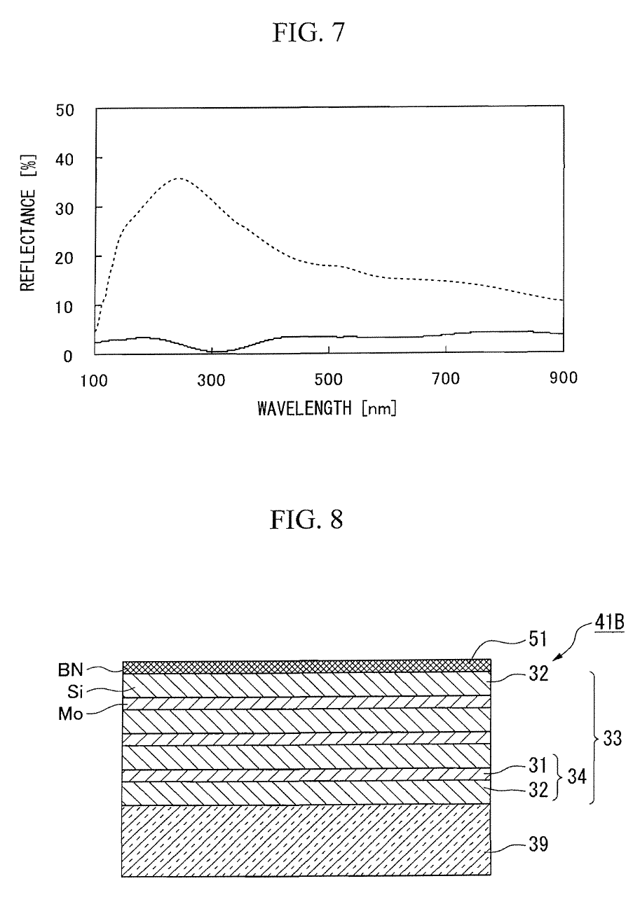

FIG. 7 shows a reflecting wavelength characteristic in the case where the first multilayer-film reflective mirror 41 shown in FIG. 3 and the second multilayer-film reflective mirror 42 shown in FIG. 4 are combined. The horizontal axis represents the wavelength of the OoB light L2 incident on the multilayer-film reflective mirror. The vertical axis represents the reflectance of the multilayer-film reflective mirror with respect to the incident OoB light L2. In FIG. 7, the solid line represents a total reflectance of the first multilayer-film reflective mirror 41 and the second multilayer-film reflective mirror 42 for the OoB light L2 in a wavelength region from a wavelength of 100 nm to a wavelength of 900 nm. FIG. 7 shows the case where the incident angle of light with respect to the surface of the multilayer film 33 (the surfaces of the absorption layers 50, 60) is approximately 90 degrees. Note that as a comparative example, the dashed line represents a reflectance for the OoB light L2 in the case where two multilayer-film reflective mirrors without an absorption layer are combined.

As shown in FIG. 7, the combination of the first multilayer-film reflective mirror 41 and the second multilayer-film reflective mirror 42 can favorably suppress the reflection of the OoB light L2 in a wide wavelength region from a wavelength of 100 nm to a wavelength of 900 nm.

As described above, in the present embodiment, by providing at least two multilayer-film reflective mirrors 41, 42 which respectively suppress a reflection of the OoB light in different wavelength regions, the OoB light L2 can be favorably decreased or eliminated in a wide wavelength region. It is possible for example to favorably suppress the incidence of the OoB light L2 emitted from the light source apparatus 3 to objects on the downstream side of the optical path of the illumination optical system IL, or the irradiation of the light onto a portion which is not expected to be irradiated by the light. Therefore, for example because the heating of the illumination optical system IL by the irradiation of the OoB light L2 can be suppressed, the deterioration in optical performance of the illumination optical system IL can be suppressed. Furthermore, because the heating of the mask M by the irradiation of the OoB light L2 can be suppressed, a thermal deformation and the like of the mask M can be suppressed, and hence the occurrence of defective exposure can be suppressed. Furthermore, for example because the heating of the projection optical system PL by the irradiation of the OoB light L2 can be suppressed, the deterioration in optical performance (imaging characteristics) of the projection optical system PL can be suppressed. Furthermore, because the incidence of the OoB light L2 on the substrate P can be suppressed, unnecessary exposure of the substrate P, heating of the substrate P, or the like can be suppressed. Therefore, the occurrence of defective exposure can be suppressed.

### Second Embodiment

Next is a description of a second embodiment. In the following description, components the same as or similar to those of the aforementioned embodiment are denoted by the same reference symbols, and descriptions thereof are simplified or omitted.

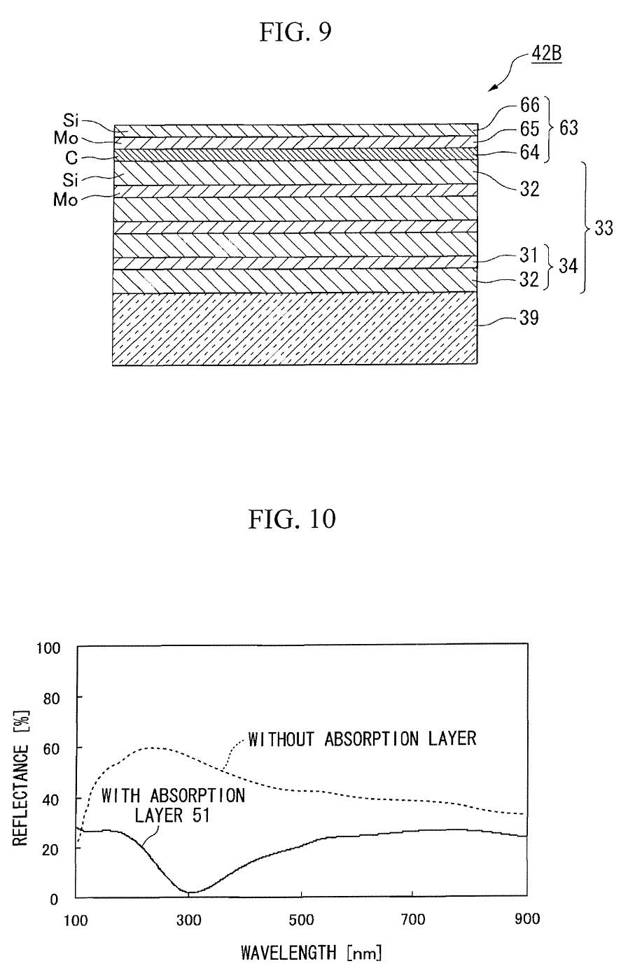

In the present embodiment, the case is described where of the condensing mirror 10 and the plurality of multilayer-film reflective mirrors 11 to 15 of the illumination optical system IL, at least one multilayer-film reflective mirror is a first multilayer-film reflective mirror 41B shown in FIG. 8, and at least one multilayer-film reflective mirror is a second multilayer-film reflective mirror 42B shown in FIG. 9.

First, the first multilayer-film reflective mirror 41B will be described. In FIG. 8, the first multilayer-film reflective mirror 41B includes: a base 39; a multilayer film 33 that includes first layers 31 and second layers 32 alternately laminated on the base 39 at a predetermined periodic length “d” and is capable of reflecting the EUV light L1; and an absorption layer 51 that is formed so as to be in contact with a surface of the multilayer film 33 for absorbing the OoB light L2 in at least a part of a wavelength region (ultraviolet region) other than the extreme ultraviolet region.

In the present embodiment, the base 39, the first layers 31, and the second layers 32 of the first multilayer-film reflective mirror 41B are equivalent to the base 39, the first layers 31, and the second layers 32 of the first multilayer-film reflective mirror 41 which is described in the aforementioned first embodiment. A description of the base 39, the first layers 31, and the second layers 32 of the first multilayer-film reflective mirror 41B is omitted.

In FIG. 8, the absorption layer 51 is formed of boron nitride (BN). As one example, in the present embodiment, the absorption layer 51 has a thickness of 24 nm.

Next, the second multilayer-film reflective mirror 42B will be described. In FIG. 9, the second multilayer-film reflective mirror 42B includes: a base 39; a multilayer film 33 that includes first layers 31 and second layers 32 alternately laminated on the base 39 at a predetermined periodic length “d” and is capable of reflecting the EUV light L1; and an absorption layer 63 that is formed so as to be in contact with a surface of the multilayer film 33 for absorbing the OoB light L2 in at least a part of a wavelength region (ultraviolet region) other than the extreme ultraviolet region.

In the present embodiment, the base 39, the first layers 31, and the second layers 32 of the second multilayer-film reflective mirror 42B are equivalent to the base 39, the first layers 31, and the second layers 32 of the first multilayer-film reflective mirror 41 which is described in the aforementioned first embodiment. A description of the base 39, the first layers 31, and the second layers 32 of the second multilayer-film reflective mirror 42B is omitted.

In FIG. 9, the absorption layer 63 includes: a first absorption layer 64 made of a first substance and formed so as to be in contact with a surface of the multilayer film 33; and second absorption layers 65, 66 made of a second substance (or second substances) that are formed so as to be in contact with a surface of the first absorption layer 64. In the present embodiment, the first absorption layer 64 is formed of carbon (C), and the second absorption layers 65, 66 include: a first layer 65 formed of molybdenum (Mo); and a layer 66 formed of silicon (Si) so as to be in contact with a surface of the layer 65 formed of molybdenum. That is, the absorption layer 63 provided on the second multilayer-film reflective mirror 42B is formed of the three absorption layers of: the absorption layer 64 formed of carbon (C); the absorption layer 65 formed of molybdenum (Mo); and the absorption layer 66 formed of silicon (Si). As one example, in the present embodiment, the absorption layer 64 has a thickness of 30 nm, the absorption layer 65 has a thickness of 1 nm, and the absorption layer 66 has a thickness of 6 nm.

FIG. 10 shows a reflecting wavelength characteristic of the first multilayer-film reflective mirror 41B shown in FIG. 8. The horizontal axis represents the wavelength of the OoB light L2 incident on the multilayer-film reflective mirror. The vertical axis represents the reflectance of the multilayer-film reflective mirror with respect to the incident OoB light L2. In FIG. 10, the solid line represents a reflectance of the first multilayer-film reflective mirror 41B for the OoB light L2 in a wavelength region from a wavelength of 100 nm to a wavelength of 900 nm. FIG. 10 shows the case where the incident angle of light with respect to the surface of the multilayer film 33 (the surface of the absorption layer 51) is approximately 90 degrees. Note that as a comparative example, the dashed line represents a reflectance of a multilayer-film reflective mirror without an absorption layer for the OoB light L2.

As shown in FIG. 10, the first multilayer-film reflective mirror 41B in the present embodiment can favorably suppress the reflection of the OoB light L2 in a wavelength region near a wavelength of 300 nm.

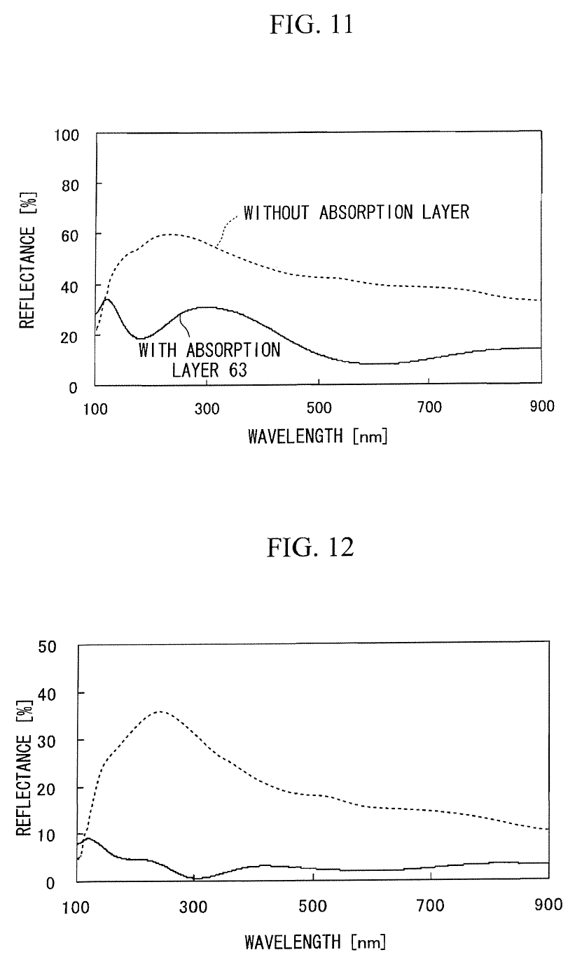

FIG. 11 shows a reflecting wavelength characteristic of the second multilayer-film reflective mirror 42B shown in FIG. 9. The horizontal axis represents the wavelength of the OoB light L2 incident on the multilayer-film reflective mirror. The vertical axis represents the reflectance of the multilayer-film reflective mirror with respect to the incident OoB light L2. In FIG. 11, the solid line represents a reflectance of the second multilayer-film reflective mirror 42B for the OoB light L2 in a wavelength region from a wavelength of 100 nm to a wavelength of 900 nm. FIG. 11 shows the case where the incident angle of light with respect to the surface of the multilayer film 33 (the surface of the absorption layer 63) is approximately 90 degrees. Note that as a comparative example, the dashed line represents a reflectance of a multilayer-film reflective mirror without an absorption layer for the OoB light L2.

As shown in FIG. 11, the second multilayer-film reflective mirror 42B in the present embodiment can favorably suppress the reflection of the OoB light L2 in a wavelength region near a wavelength of 600 nm.

FIG. 12 shows a reflecting wavelength characteristic in the case where the first multilayer-film reflective mirror 41B shown in FIG. 8 and the second multilayer-film reflective mirror 42B shown in FIG. 9 are combined. The horizontal axis represents the wavelength of the OoB light L2 incident on the multilayer-film reflective mirror. The vertical axis represents the reflectance of the multilayer-film reflective mirror with respect to the incident OoB light L2. In FIG. 12, the solid line represents a total reflectance of the first multilayer-film reflective mirror 41B and the second multilayer-film reflective mirror 42B for the OoB light L2 in a wavelength region from a wavelength of 100 nm to a wavelength of 900 nm. FIG. 12 shows the case where the incident angle of light with respect to the surface of the multilayer film 33 (the surfaces of the absorption layers 51, 63) is approximately 90 degrees. Note that as a comparative example, the dashed line represents a reflectance for the OoB light L2 in the case where two multilayer-film reflective mirrors without an absorption layer are combined.

As shown in FIG. 12, the combination of the first multilayer-film reflective mirror 41B and the second multilayer-film reflective mirror 42B can favorably suppress the reflection of the OoB light L2 in a wide wavelength region from a wavelength of 100 nm to a wavelength of 900 nm.

### Third Embodiment

Next is a description of a third embodiment. In the following description, components the same as or similar to those of the aforementioned embodiments are denoted by the same reference symbols, and descriptions thereof are simplified or omitted.

In the present embodiment, the case is described where of the condensing mirror 10 and the plurality of multilayer-film reflective mirrors 11 to 15 of the illumination optical system IL, at least one multilayer-film reflective mirror is a first multilayer-film reflective mirror 41 shown in FIG. 3 above, and at least one multilayer-film reflective mirror is a second multilayer-film reflective mirror 42C shown in FIG. 13.

The first multilayer-film reflective mirror is the first multilayer-film reflective mirror 41 which was described with reference to FIG. 3 above, and hence the description thereof is omitted. Furthermore, the reflecting wavelength characteristic of the first multilayer-film reflective mirror 41 was described with reference to FIG. 5, and hence the description thereof is omitted.

Next, the second multilayer-film reflective mirror 42C will be described. In FIG. 13, the second multilayer-film reflective mirror 42C includes: a base 39; a multilayer film 33 that includes first layers 31 and second layers 32 alternately laminated on the base 39 at a predetermined periodic length “d” and is capable of reflecting the EUV light L1; and an absorption layer 67 that is formed so as to be in contact with a surface of the multilayer film 33 for absorbing the OoB light L2 in at least a part of a wavelength region (ultraviolet region) other than the extreme ultraviolet region.

In the present embodiment, the base 39, the first layers 31, and the second layers 32 of the second multilayer-film reflective mirror 42C are equivalent to the base 39, the first layers 31, and the second layers 32 of the first multilayer-film reflective mirror 41 which is described in the aforementioned first embodiment. A description of the base 39, the first layers 31, and the second layers 32 of the second multilayer-film reflective mirror 42C is omitted.

In FIG. 13, the absorption layer 67 includes: a first absorption layer 68 made of a first substance and formed so as to be in contact with a surface of the multilayer film 33; and a second absorption layer 69 made of a second substance and formed so as to be in contact with a surface of the first absorption layer 68. In the present embodiment, the first absorption layer 68 is formed of boron nitride (BN), and the second absorption layer 69 is formed of silicon (Si). As one example, in the present embodiment, the first absorption layer 68 has a thickness of 24 nm, and the second absorption layer 69 has a thickness of 6 nm.

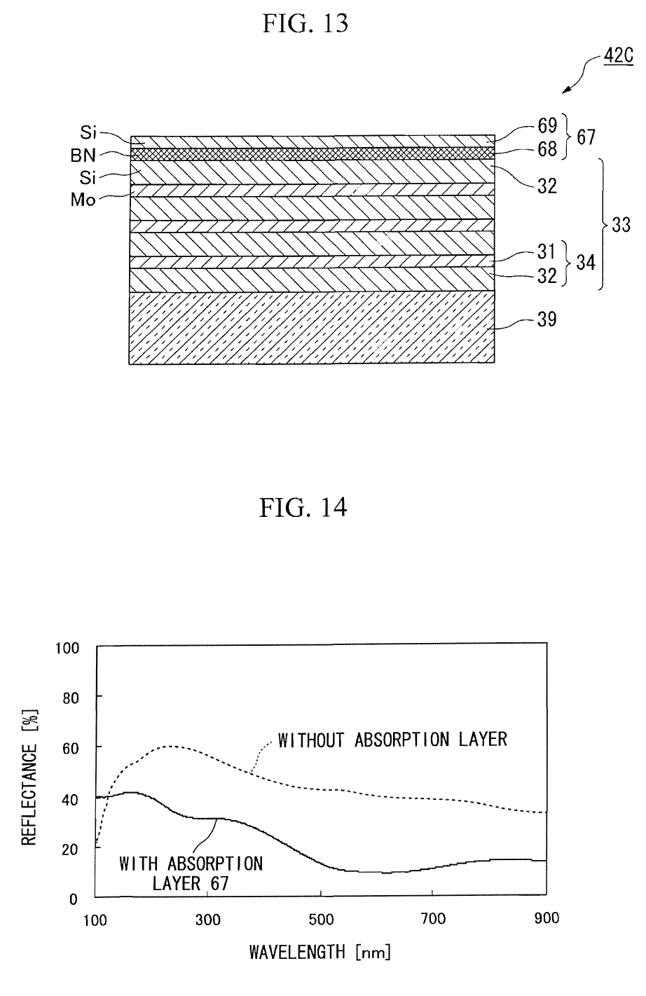

FIG. 14 shows a reflecting wavelength characteristic of the second multilayer-film reflective mirror 42C shown in FIG. 13. The horizontal axis represents the wavelength of the OoB light L2 incident on the multilayer-film reflective mirror. The vertical axis represents the reflectance of the multilayer-film reflective mirror with respect to the incident OoB light L2. In FIG. 14, the solid line represents a reflectance of the second multilayer-film reflective mirror 42C for the OoB light L2 in a wavelength region from a wavelength of 100 nm to a wavelength of 900 nm. FIG. 14 shows the case where the incident angle of light with respect to the surface of the multilayer film 33 (the surface of the absorption layer 67) is approximately 90 degrees. Note that as a comparative example, the dashed line represents a reflectance of a multilayer-film reflective mirror without an absorption layer for the OoB light.

As shown in FIG. 14, the second multilayer-film reflective mirror 42C in the present embodiment can favorably suppress the reflection of the OoB light L2 in a wavelength region near a wavelength of 600 nm.

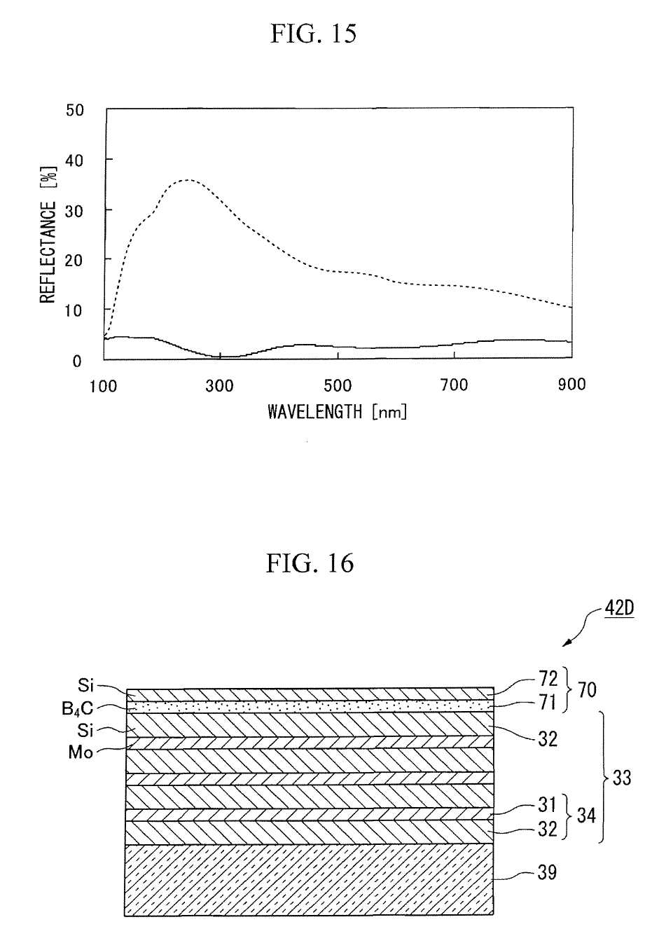

FIG. 15 shows a reflecting wavelength characteristic in the case where the first multilayer-film reflective mirror 41 shown in FIG. 3 and the second multilayer-film reflective mirror 42C shown in FIG. 13 are combined. The horizontal axis represents the wavelength of the OoB light L2 incident on the multilayer-film reflective mirror. The vertical axis represents the reflectance of the multilayer-film reflective mirror with respect to the incident OoB light L2. In FIG. 15, the solid line represents a total reflectance of the first multilayer-film reflective mirror 41 and the second multilayer-film reflective mirror 42C for the OoB light L2 in a wavelength region from a wavelength of 100 nm to a wavelength of 900 nm. FIG. 15 shows the case where the incident angle of light with respect to the surface of the multilayer film 33 (the surfaces of the absorption layers 50, 67) is approximately 90 degrees. Note that as a comparative example, the dashed line represents a reflectance for the OoB light L2 in the case where two multilayer-film reflective mirrors without an absorption layer are combined.

As shown in FIG. 15, the combination of the first multilayer-film reflective mirror 41 and the second multilayer-film reflective mirror 42C can favorably suppress the reflection of the OoB light L2 in a wide wavelength region from a wavelength of 100 nm to a wavelength of 900 nm.

### Fourth Embodiment

Next is a description of a fourth embodiment. In the following description, components the same as or similar to those of the aforementioned embodiments are denoted by the same reference symbols, and descriptions thereof are simplified or omitted.

In the present embodiment, the case is described where of the condensing mirror 10 and the plurality of multilayer-film reflective mirrors 11 to 15 of the illumination optical system IL, at least one multilayer-film reflective mirror is a first multilayer-film reflective mirror 41B shown in FIG. 8 above, and at least one multilayer-film reflective mirror is a second multilayer-film reflective mirror 42D shown in FIG. 16.

The first multilayer-film reflective mirror is the first multilayer-film reflective mirror 41B which was described with reference to FIG. 8 above, and hence the description thereof is omitted. Furthermore, the reflecting wavelength characteristic of the first multilayer-film reflective mirror 41 B was described with reference to FIG. 10, and hence the description thereof is omitted.

Next, the second multilayer-film reflective mirror 42D will be described. In FIG. 16, the second multilayer-film reflective mirror 42D includes: a base 39; a multilayer film 33 that includes first layers 31 and second layers 32 alternately laminated on the base 39 at a predetermined periodic length “d” and is capable of reflecting the EUV light L1; and an absorption layer 70 that is formed so as to be in contact with a surface of the multilayer film 33 for absorbing the OoB light L2 in at least a part of a wavelength region (ultraviolet region) other than the extreme ultraviolet region.

In the present embodiment, the base 39, the first layers 31, and the second layers 32 of the second multilayer-film reflective mirror 42D are equivalent to the base 39, the first layers 31, and the second layers 32 of the multilayer-film reflective mirror 42 of the first multilayer-film reflective mirror 41 which is described in the aforementioned first embodiment. A description of the base 39, the first layers 31, and the second layers 32 of the second multilayer-film reflective mirror 42D is omitted.

In FIG. 16, the absorption layer 70 includes: a first absorption layer 71 made of a first substance and formed so as to be in contact with a surface of the multilayer film 33; and a second absorption layer 72 made of a second substance and formed so as to be in contact with a surface of the first absorption layer 71. In the present embodiment, the first absorption layer 71 is formed of boron carbide (B₄C), and the second absorption layer 72 is formed of silicon (Si). As one example, in the present embodiment, the first absorption layer 71 has a thickness of 31 nm, and the second absorption layer 72 has a thickness of 3 nm.

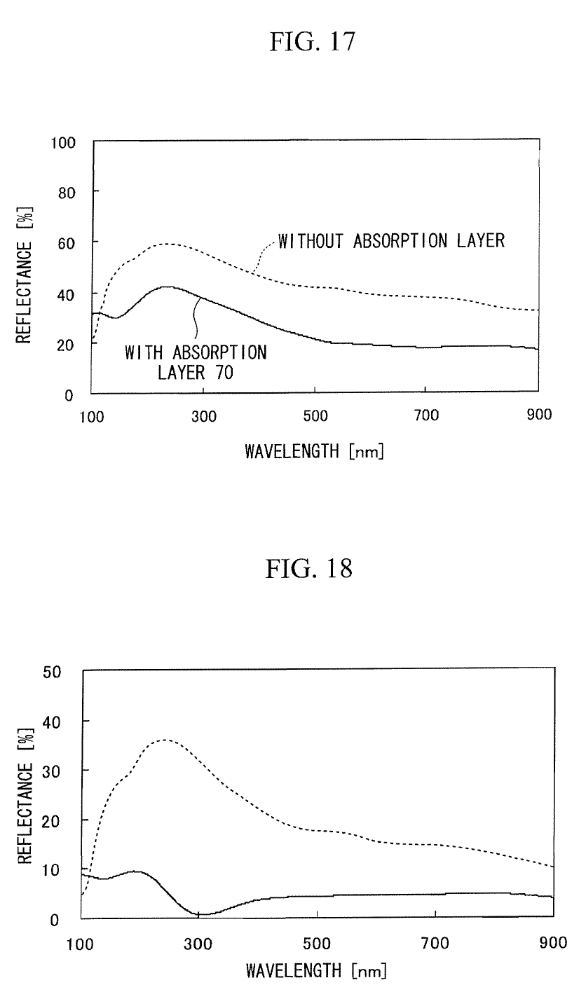

FIG. 17 shows a reflecting wavelength characteristic of the second multilayer-film reflective mirror 42D shown in FIG. 16. The horizontal axis represents the wavelength of the OoB light L2 incident on the multilayer-film reflective mirror. The vertical axis represents the reflectance of the multilayer-film reflective mirror with respect to the incident OoB light L2. In FIG. 17, the solid line represents a reflectance of the second multilayer-film reflective mirror 42D for the OoB light L2 in a wavelength region from a wavelength of 100 nm to a wavelength of 900 nm. FIG. 17 shows the case where the incident angle of light with respect to the surface of the multilayer film 33 (the surface of the absorption layer 70) is approximately 90 degrees. Note that as a comparative example, the dashed line represents a reflectance of a multilayer-film reflective mirror without an absorption layer for the OoB light.

As shown in FIG. 17, the second multilayer-film reflective mirror 42D in the present embodiment can favorably suppress the reflection of the OoB light L2 in a wavelength region near a wavelength of 600 nm.

FIG. 18 shows a reflecting wavelength characteristic in the case where the first multilayer-film reflective mirror 41B shown in FIG. 8 and the second multilayer-film reflective mirror 42D shown in FIG. 16 are combined. The horizontal axis represents the wavelength of the OoB light L2 incident on the multilayer-film reflective mirror. The vertical axis represents the reflectance of the multilayer-film reflective mirror with respect to the incident OoB light L2. In FIG. 18, the solid line represents a total reflectance of the first multilayer-film reflective mirror 41B and the second multilayer-film reflective mirror 42D for the OoB light L2 in a wavelength region from a wavelength of 100 nm to a wavelength of 900 nm. FIG. 18 shows the case where the incident angle of light with respect to the surface of the multilayer film 33 (the surfaces of the absorption layers 51, 70) is approximately 90 degrees. Note that as a comparative example, the dashed line represents a reflectance for the OoB light L2 in the case where two multilayer-film reflective mirrors without an absorption layer are combined.

As shown in FIG. 18, the combination of the first multilayer-film reflective mirror 41B and the second multilayer-film reflective mirror 42D can favorably suppress the reflection of the OoB light L2 in a wide wavelength region from a wavelength of 100 nm to a wavelength of 900 nm.

### Fifth Embodiment

Next is a description of a fifth embodiment. In the following description, components the same as or similar to those of the aforementioned embodiments are denoted by the same reference symbols, and descriptions thereof are simplified or omitted.

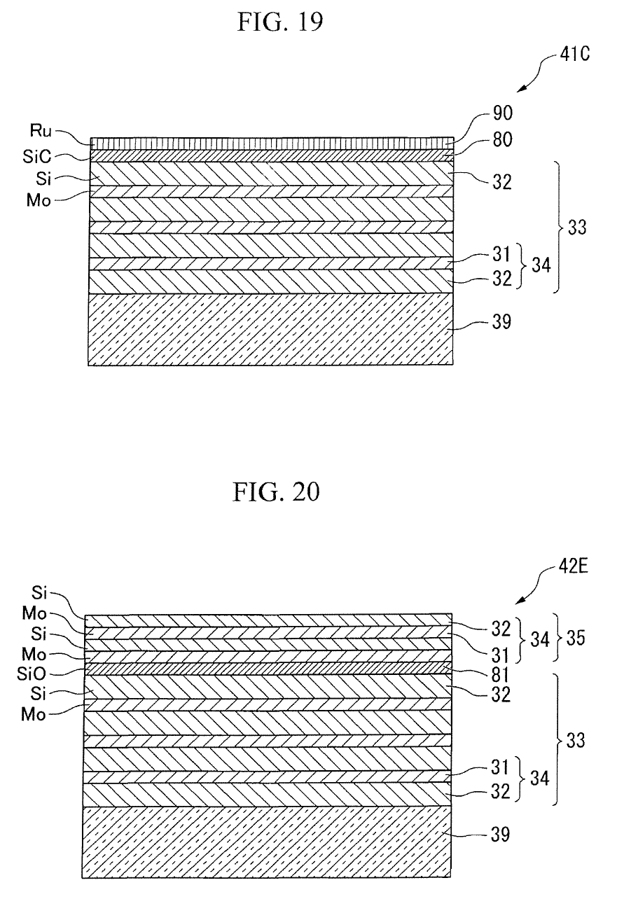

In the present embodiment, the case is described where of the condensing mirror 10 and the plurality of multilayer-film reflective mirrors 11 to 15 of the illumination optical system IL, at least one multilayer-film reflective mirror is a first multilayer-film reflective mirror 41C shown in FIG. 19, and at least one multilayer-film reflective mirror is a second multilayer-film reflective mirror 42E shown in FIG. 20.

First, the first multilayer-film reflective mirror 41C will be described. In FIG. 19, the first multilayer-film reflective mirror 41C includes: a base 39; a multilayer film 33 that includes first layers 31 and second layers 32 alternately laminated on the base 39 at a predetermined periodic length “d” and is capable of reflecting the EUV light L1; and an absorption layer 80 that is formed so as to be in contact with a surface of the multilayer film 33 for absorbing the OoB light L2 in at least a part of a wavelength region (ultraviolet region) other than the extreme ultraviolet region, and a protection layer 90 that is formed so as to be in contact with a surface of the absorption layer 80.

In the present embodiment, the base 39, the first layers 31, and the second layers 32 of the first multilayer-film reflective mirror 41C are equivalent to the base 39, the first layers 31, and the second layers 32 of the first multilayer-film reflective mirror 41 which is described in the aforementioned first embodiment. A description of the base 39, the first layers 31, and the second layers 32 of the first multilayer-film reflective mirror 41C is omitted.

In FIG. 19, the absorption layer 80 of the first multilayer-film reflective mirror 41C is formed of silicon carbide (SiC). As one example, in the present embodiment, the absorption layer 80 has a thickness of 17 nm.

Furthermore, in FIG. 19, the protection layer 90 of the first multilayer-film reflective mirror 41 C is formed of ruthenium (Ru). As one example, in the present embodiment, the protection layer 90 has a thickness of 2 nm.

In the present embodiment, the protection layer 90 acts as a layer which inhibits oxidation of the surface of the multilayer-film reflective mirror, or a protection layer acting at removing a contamination (e.g., a carbon contamination, which consists primarily of carbon) attached on the surface of the multilayer-film reflective mirror. Alternatively or also, the protection layer 90 can be formed of a compound with ruthenium (e.g., ruthenium alloy), an oxide with ruthenium, silicon (Si), titanium (Ti), or the like.

Next, the second multilayer-film reflective mirror 42E will be described. In FIG. 20, the second multilayer-film reflective mirror 42E includes: a base 39; a multilayer film 33 that includes first layers 31 and second layers 32 alternately laminated on the base 39 at a predetermined periodic length “d” and is capable of reflecting the EUV light L1; and an absorption layer 81 that is formed so as to be in contact with a surface of the multilayer film 33 for absorbing the OoB light L2 in at least a part of a wavelength region (ultraviolet region) other than the extreme ultraviolet region, and a multilayer film 35 that is formed so as to be in contact with a surface of the absorption layer 81 and includes two layer pairs 34 of the first layers 31 and the second layers 32.

In the present embodiment, the base 39, the first layers 31, and the second layers 32 of the second multilayer-film reflective mirror 42E are equivalent to the base 39, the first layers 31, and the second layers 32 of the first multilayer-film reflective mirror 41 which is described in the aforementioned first embodiment. A description of the base 39, the first layers 31, and the second layers 32 of the second multilayer-film reflective mirror 42E is omitted.

In FIG. 20, the absorption layer 81 of the second multilayer-film reflective mirror 42E is formed of silicon monoxide (SiO).As one example, in the present embodiment, the absorption layer 81 has a thickness of 28 nm.

Furthermore, in FIG. 20, the multilayer film 35 of the second multilayer-film reflective mirror 42E is formed of two layer pairs 34. As one example, in the present embodiment, the multilayer film 35 has a thickness of 14 nm, when each one pair of the layer pairs 34 has a thickness of 7 nm.

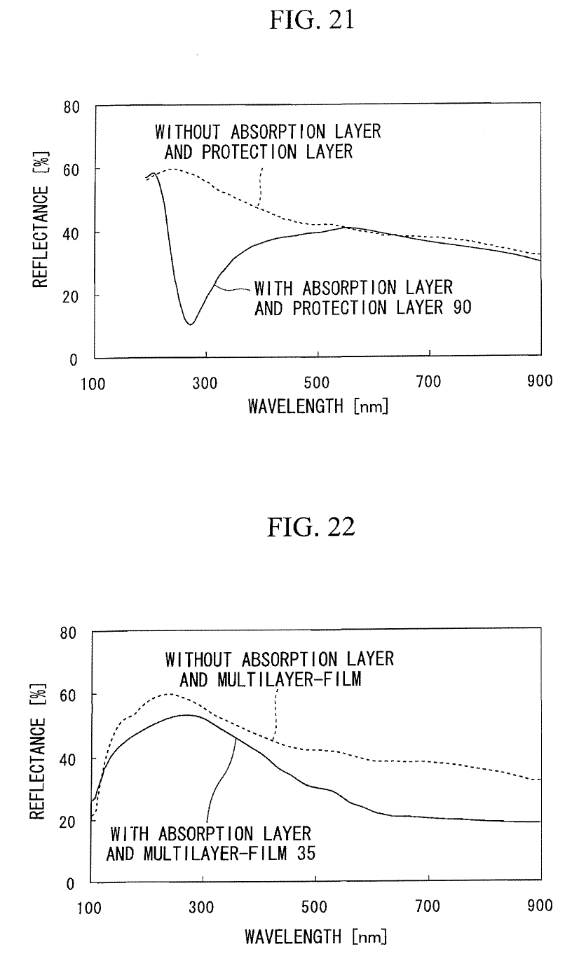

FIG. 21 shows a reflecting wavelength characteristic of the first multilayer-film reflective mirror 41 C shown in FIG. 19. The horizontal axis represents the wavelength of the OoB light L2 incident on the multilayer-film reflective mirror. The vertical axis represents the reflectance of the multilayer-film reflective mirror for the incident OoB light L2. In FIG. 21, the solid line represents a reflectance of the first multilayer-film reflective mirror 41C for the OoB light L2 in a wavelength region from a wavelength of 190 nm to a wavelength of 900 nm. FIG. 21 shows the case where the incident angle of light with respect to the surface of the multilayer film 33 (the surface of the protection layer 90) is approximately 90 degrees. Note that as a comparative example, the dashed line represents a reflectance, for the OoB light L2, of a multilayer-film reflective mirror with no absorption layer and no protection layer.

As shown in FIG. 21, the first multilayer-film reflective mirror 41C in the present embodiment can favorably suppress the reflection of the OoB light L2 especially in a wavelength region near a wavelength of 270 nm.

FIG. 22 shows a reflecting wavelength characteristic of the second multilayer-film reflective mirror 42E shown in FIG. 20. The horizontal axis represents the wavelength of the OoB light L2 incident on the multilayer-film reflective mirror. The vertical axis represents the reflectance of the multilayer-film reflective mirror for the incident OoB light L2. In FIG. 22, the solid line represents a reflectance of the second multilayer-film reflective mirror 42E for the OoB light L2 in a wavelength region from a wavelength of 100 nm to a wavelength of 900 nm. FIG. 22 shows the case where the incident angle of light with respect to the surface of the multilayer film 33 (the surface of the multilayer film 35) is approximately 90 degrees. Note that as a comparative example, the dashed line represents a reflectance of a multilayer-film reflective mirror with no absorption layer and no multilayer film 35, for the OoB light L2.

As shown in FIG. 22, the second multilayer-film reflective mirror 42E in the present embodiment can favorably suppress the reflection of the OoB light L2 especially in a wavelength region near a wavelength of 600 nm.

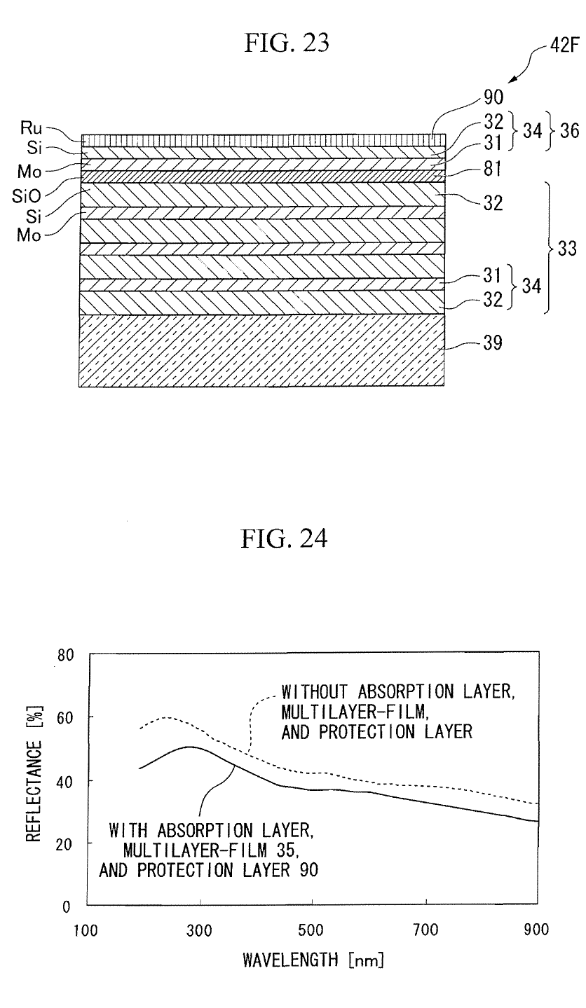

Next, in the present embodiment, a case where at least one of the multilayer-film reflective mirrors is composed of the second multilayer-film reflective mirror 42F shown in FIG. 23, will be described.

In FIG. 23, the second multilayer-film reflective mirror 42F includes: a base 39; a multilayer film 33 that includes first layers 31 and second layers 32 alternately laminated on the base 39 at a predetermined periodic length “d” and is capable of reflecting the EUV light L1; and an absorption layer 81 that is formed so as to be in contact with a surface of the multilayer film 33 for absorbing the OoB light L2 in at least a part of a wavelength region (ultraviolet region) other than the extreme ultraviolet region, a multilayer film 36 that is formed so as to be in contact with a surface of the absorption layer 81 and includes one layer pair 34 of the first layer 31 and the second layer 32, and a protection layer 90 that is formed so as to be in contact with a surface of the multilayer film 36.

In the present embodiment, the base 39, the first layer(s) 31, and the second layer(s) 32 of the second multilayer-film reflective mirror 42F are equivalent to the base 39, the first layers 31, and the second layers 32 of the first multilayer-film reflective mirror 41 which is described in the aforementioned first embodiment. In addition, the absorption layer 81 of the second multilayer-film reflective mirror 42F is equivalent to the absorption layer 81 of the second multilayer-film reflective mirror 42E, which is described in this embodiment. In addition, the protection layer 90 of the second multilayer-film reflective mirror 42F is equivalent to the protection layer 90 of the first multilayer-film reflective mirror 41C, which is described in this embodiment. A description of the base 39, the first layer(s) 31, the second layer(s) 32, the absorption layer 81, and the protection layer 90 of the second multilayer-film reflective mirror 42F is omitted.

Furthermore, in FIG. 23, the multilayer film 36 of the second multilayer-film reflective mirror 42F is formed of one layer pair 34. As one example, in the present embodiment, the multilayer film 36 has a thickness of 7 nm.

FIG. 24 shows a reflecting wavelength characteristic of the second multilayer-film reflective mirror 42F shown in FIG. 23. The horizontal axis represents the wavelength of the OoB light L2 incident on the multilayer-film reflective mirror. The vertical axis represents the reflectance of the multilayer-film reflective mirror for the incident OoB light L2. In FIG. 24, the solid line represents a reflectance of the second multilayer-film reflective mirror 42F for the OoB light L2 in a wavelength region from a wavelength of 190 nm to a wavelength of 900 nm. FIG. 24 shows the case where the incident angle of light with respect to the surface of the multilayer film 33 (the surface of the protection layer 90) is approximately 90 degrees. Note that as a comparative example, the dashed line represents a reflectance, for the OoB light L2, of a multilayer-film reflective mirror with no multilayer film 36 and no protection layer.

As shown in FIG. 24, the second multilayer-film reflective mirror 42F in the present embodiment can favorably suppress the reflection of the OoB light L2 especially in a wavelength region near a wavelength of 650 nm.

The combination of the first multilayer-film reflective mirror 41C and the second multilayer-film reflective mirror 42E can favorably suppress the reflection of the OoB light L2 in a wide wavelength region from a wavelength of 100 nm to a wavelength of 900 nm. Furthermore, the combination of the first multilayer-film reflective mirror 41C and the second multilayer-film reflective mirror 42F can favorably suppress the reflection of the OoB light L2 in a wide wavelength region from a wavelength of 100 nm to a wavelength of 900 nm.

In the above first to fifth embodiments, the description has been made of the case where the illumination optical system IL is provided with two multilayer-film reflective mirrors which respectively suppress a reflection of the OoB light L2 in a different wavelength region, by way of example. However, obviously, the illumination optical system IL can be provided with any number (more than two) of multilayer-film reflective mirrors with different wavelength regions in which the reflection of the OoB light L2 is suppressed. As a result, the reflection of the OoB light L2 can be suppressed in a wider wavelength region.

In the above respective embodiments, the description has been made of the case where the multilayer-film reflective mirrors for suppressing the reflection of the OoB light L2 are arranged in the illumination optical system IL, by way of example. However, the projection optical system PL, which guides the light from the mask M to the substrate P, can be provided with the multilayer-film reflective mirrors for suppressing the reflection of the OoB light L2. Also as a result of this, the deterioration in optical performance of the projection optical system PL can be suppressed, and the occurrence of defective exposure can be suppressed.

In the above respective embodiments, the description has been made of the case where the multilayer-film reflective mirrors for suppressing the reflection of the OoB light L2 are arranged in an optical apparatus (illumination optical system IL, projection optical system PL) of the exposure apparatus EX, by way of example. However, obviously, the multilayer-film reflective mirrors for suppressing the reflection of the OoB light L2 can be arranged in an optical apparatus other than the exposure apparatus EX. In the case where the optical apparatus uses each of a plurality of multilayer-film reflective mirrors to reflect light (electromagnetic wave) in the extreme ultraviolet region from a first position, to thereby guide the light to a second position, multilayer-film reflective mirrors for suppressing the reflection of the OoB light L2 are arranged in the optical apparatus. Thereby, the deterioration in optical performance of the optical apparatus can be suppressed, and the irradiation of the OoB light L2 onto the second position can be suppressed.

In the above respective embodiments, the description has been made of the case where the multilayer film 33, 35, 36 is a Mo/Si multilayer film, by way of example. However, for example, a substance for forming the multilayer film can be modified according to a wavelength band of the EUV light L1. For example, in the case where EUV light in a wavelength band is near 11.3 nm, a Mo/Be multilayer film in which molybdenum layers (Mo layers) and beryllium (Be layers) are alternately laminated can be used to obtain a high reflectance.

In the above respective embodiments, as a substance for forming the first layer 31 of the multilayer film 33, 35, 36, ruthenium (Ru), molybdenum carbide (MO₂C), molybdenum oxide (MoO₂), molybdenum silicide (MoSi₂), or the like may be used. Furthermore, as a substance for forming the second layer 32 of the multilayer film 33, 35, 36, silicon carbide (SiC) can be used.

In the above respective embodiments, for example between the base 39 and the multilayer film 33, there may be provided a layer of a metal exhibiting a large thermal conductivity coefficient, such as a silver alloy, copper, a copper alloy, aluminum, an aluminum alloy, or the like. Also or alternatively, between the base 39 and the multilayer film 33, there can be provided a water-soluble foundation layer of a material, such as lithium fluoride (LiF), magnesium fluoride (MgF₂), barium fluoride (BaF₂), aluminum fluoride (AlF₃), manganese fluoride (MnF₂), zinc fluoride (ZnF₂) or the like. Alternatively, the foundation layer can comprises a low-melting-temperature alloy, such as: a eutectic alloy, eutectic alloys in 2- to 5-element systems comprising combinations of two or more elements selected from the group comprising Bi, Pb, In, Sn, and Cd; or Au—Na eutectic alloy, Na—Tl eutectic alloy, and K—Pb eutectic alloy.

Note that as for the substrate P of each of the above embodiments, not only a semiconductor wafer used in the manufacture of semiconductor devices, but also a glass substrate for a display device, a ceramic wafer for a thin film magnetic head, a master mask or reticle (synthetic quartz or silicon wafer), film member, and similar for use in an exposure apparatus, etc. can be used. Moreover, substrates are not limited to round shape, but may be rectangular or other shapes.

As for the exposure apparatus EX, in addition to a scan type exposure apparatus (scanning stepper) in which while synchronously moving the mask M and the substrate P, the pattern of the mask M is scan-exposed, a step-and-repeat type projection exposure apparatus (stepper) in which the pattern of the mask M is exposed at one time in the condition that the mask M and the substrate P are in stationary positions, and the substrate P is successively moved stepwise can be used.

Furthermore, in step-and-repeat type exposure, after a reduced image of a first pattern is transferred onto the substrate P by using the projection optical system, in the state with the first pattern and the substrate P being in respective substantially stationary positions, a reduced image of a second pattern may be exposed in a batch onto the substrate P, partially overlapped on the first pattern by using the projection optical system, in the state with the second pattern and the substrate P being in substantially stationary positions (a stitch type batch exposure apparatus). Moreover, as the stitch type exposure apparatus, a step-and-stitch type exposure apparatus in which at least two patterns are transferred onto the substrate P in a partially overlapping manner, and the substrate P is sequentially moved can be used.

Moreover, the present invention can also be applied to an exposure apparatus as disclosed for example in U.S. patent application Ser. No. 6,611,316, which combines patterns of two masks on a substrate via a projection optical system, and double exposes a single shot region on the substrate at substantially the same time, using a single scan exposure light.

Furthermore, the present invention can also be applied to a twin stage type exposure apparatus furnished with a plurality of substrate stages, as disclosed in U.S. Pat. No. 6,341,007, U.S. Pat. No. 6,400,441, U.S. Pat. No. 6,549,269, U.S. Pat. No. 6,590,634, U.S. Pat. No. 6,208,407, U.S. Pat. No. 6,262,796, etc.

Moreover, the present invention can also be applied to an exposure apparatus furnished with a substrate stage for holding a substrate, and a measurement stage on which is mounted a reference member formed with a reference mark, and/or various photoelectronic sensors, as disclosed for example in U.S. Pat. No. 6,897,963. Furthermore, the present invention can also be applied to an exposure apparatus furnished with a plurality of substrate stages and measurement stages.

The types of exposure apparatuses EX are not limited to exposure apparatuses for semiconductor element manufacture that expose a semiconductor element pattern onto a substrate P, but are also widely applicable to exposure apparatuses for the manufacture of liquid crystal display elements and for the manufacture of displays, and exposure apparatuses for the manufacture of thin film magnetic heads, image pickup devices (CCDs), micro machines, MEMS, DNA chips, and reticles or masks.

As described above, the exposure apparatus EX of the embodiments is manufactured by assembling various subsystems, including the respective constituent elements presented, so that the prescribed mechanical precision, electrical precision and optical precision can be maintained. To ensure these respective precisions, performed before and after this assembly are adjustments for achieving optical precision with respect to the various optical systems, adjustments for achieving mechanical precision with respect to the various mechanical systems, and adjustments for achieving electrical precision with respect to the various electrical systems. The process of assembly from the various subsystems to the exposure apparatus includes mechanical connections, electrical circuit wiring connections, air pressure circuit piping connections, etc. among the various subsystems. Obviously, before the process of assembly from these various subsystems to the exposure apparatus, there are the processes of individual assembly of the respective subsystems. When the process of assembly to the exposure apparatuses of the various subsystems has ended, overall assembly is performed, and the various precisions are ensured for the exposure apparatus as a whole. Note that it is preferable that the manufacture of the exposure apparatus be performed in a clean room in which the temperature, the degree of cleanliness, etc. are controlled.

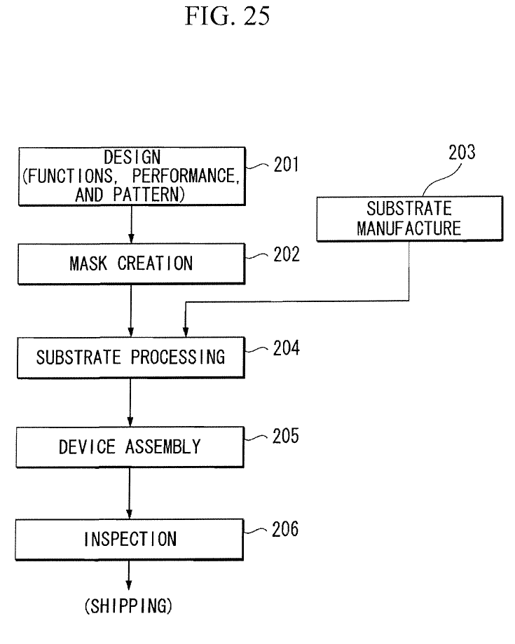

As shown in FIG. 25, microdevices such as semiconductor devices are manufactured by going through: a step 201 that performs microdevice function and performance design, a step 202 that creates the mask (reticle) based on this design step, a step 203 that manufactures the substrate that is the device base, a substrate processing step 204 including substrate processing (exposure processing) that exposes an image of the pattern on the mask onto a substrate according to the aforementioned embodiments and develops the exposed substrate, a device assembly step (including treatment processes such as a dicing process, a bonding process and a packaging process) 205, and an inspection step 206, and so on.

As far as is permitted by the law, the disclosures in all of the Publications and U.S. Patents related to exposure apparatuses and the like cited in the above respective embodiments and modified examples, are incorporated herein by reference.

Note that the embodiments of the present invention have been described as above. However, in the present invention, all the constituent elements can be used in appropriate combination. Alternately, some of the constituent elements may not be used.

1. An optical apparatus, comprising a plurality of multilayer-film reflective mirrors that are capable of reflecting an electromagnetic wave in an extreme ultraviolet region, wherein
the multilayer-film reflective mirrors are arranged along an optical axis of the electromagnetic wave, and
at least two of the multilayer-film reflective mirrors have reflecting wavelength characteristics being different from each other, in a wavelength region other than the extreme ultraviolet region.

2. The optical apparatus according to claim 1, wherein the wavelength region other than the extreme ultraviolet region comprises a wavelength region longer than the extreme ultraviolet region.

3. The optical apparatus according to claim 1, wherein the multilayer film of the multilayer-film reflective mirror comprises first layers and second layers which are alternately laminated on a base, and
the multilayer-film reflective mirror comprises an absorption layer that is formed so as to be in contact with a surface of the multilayer film and that absorbs the electromagnetic wave in at least a part of the wavelength region other than the extreme ultraviolet region.

4. The optical apparatus according to claim 3, wherein a difference between a refractive index of the first layer to extreme ultraviolet light and a refractive index of a vacuum is larger than a difference between a refractive index of the second layer to extreme ultraviolet light and a refractive index of a vacuum.

5. The optical apparatus according to claim 3, wherein the first layer comprises Mo, the second layer comprises Si or Be, and the surface of the multilayer film is formed of the second layer.

6. The optical apparatus according to claim 3, wherein the absorption layer comprises at least one of SiO, BN, C, B₄C, Si, Sic, and Mo.

7. The optical apparatus according to claim 3, wherein the absorption layer comprises:
a first absorption layer formed of a first substance and formed so as to be in contact with the surface of the multilayer film; and
a second absorption layer formed of a second substance and formed so as to be in contact with a surface of the first absorption layer.

8. The optical apparatus according to claim 7, wherein the first absorption layer comprises SiO, and the second absorption layer comprises Si.

9. The optical apparatus according to claim 7, wherein the first absorption layer comprises BN, and the second absorption layer comprises Si.

10. The optical apparatus according to claim 7, wherein the first absorption layer comprises B₄C, and the second absorption layer comprises Si.

11. The optical apparatus according to claim 7, wherein the first absorption layer comprises C, and the second absorption layer comprises a layer comprising Mo, and a layer comprising Si and formed so as to be in contact with a surface of the layer comprising Mo.

12. The optical apparatus according to claim 1, wherein an electromagnetic wave in an extreme ultraviolet region from a first position is reflected at each of the plurality of multilayer film reflective mirrors and then is guided to a second position.

13. The optical apparatus according to claim 12, wherein a light source apparatus is arranged at the first position, and a mask on which a pattern is formed is arranged at the second position, and
an electromagnetic wave from the light source apparatus is guided to the mask.

14. The optical apparatus according to claim 12, wherein a mask on which is formed a pattern is arranged at the first position, and a photosensitive substrate is arranged at the second position, and
an electromagnetic wave from the mask is guided to the substrate.

15. The optical apparatus according to claim 14, wherein the substrate is exposed with an electromagnetic wave at a predetermined wavelength region, and
the wavelength region other than the extreme ultraviolet region is longer than the extreme ultraviolet region and comprises at least a part of the predetermined wavelength region.

16. A multilayer-film reflective mirror, comprising:
a base;
a multilayer film that comprises first layers and second layers alternately laminated on the base, and is capable of reflecting an electromagnetic wave in an extreme ultraviolet region; and
an absorption layer that is formed so as to be in contact with a surface of the multilayer film and that absorbs an electromagnetic wave in at least a part of a wavelength region other than the extreme ultraviolet region, the absorption layer comprising a first absorption layer, made of a first substance, that is formed so as to be in contact with the surface of the multilayer film, and a second absorption layer, made of a second substance, that is formed so as to be in contact with a surface of the first absorption layer.

17. The multilayer-film reflective mirror according to claim 16, wherein the first absorption layer comprises SiO, and the second absorption layer comprises Si.

18. The multilayer-film reflective mirror according to claim 16, wherein the first absorption layer comprises BN, and the second absorption layer comprises Si.

19. The multilayer-film reflective mirror according to claim 16, wherein the first absorption layer comprises B4C, and the second absorption layer comprises Si.

20. The multilayer-film reflective mirror according to claim 16, wherein the first absorption layer comprises C, and the second absorption layer comprises a layer comprising Mo, and a layer comprising Si and formed so as to be in contact with a surface of the layer comprising Mo.

21. An exposure apparatus that exposes a substrate with exposure light, comprising:
the optical apparatus according to claim 1.

22. The exposure apparatus according to claim 21, comprising:
an illumination optical system that illuminates a mask with exposure light; and
a projection optical system that projects an image of a pattern on the mask illuminated with the exposure light onto the substrate, wherein
at least either one of the illumination optical system and the projection optical system comprises the optical apparatus.

23. A device manufacturing method, comprising:
exposing a substrate by using the exposure apparatus according to claim 21; and
developing the exposed substrate.
